(19) United States
(12) Patent Application Publication
(10) Pub. No.: US 2022/0097482 A1
(43) Pub. Date: Mar. 31, 2022

(54) HEAT-EXHAUSTING DEVICE, VEHICLE-MOUNTED DEVICE, AND FEE MACHINE

(71) Applicant: MITSUBISHI HEAVY INDUSTRIES MACHINERY SYSTEMS, LTD., Kobe-shi, Hyogo (JP)

(72) Inventors: Yusuke IBUKI, Tokyo (JP); Yohei KOJIMA, Tokyo (JP); Hiroyuki NAKAYAMA, Tokyo (JP)

(21) Appl. No.: 17/423,004

(22) PCT Filed: Jan. 18, 2019
(86) PCT No.: PCT/JP2019/001425

§ 371 Date: Jul. 14, 2021

(51) Int. Cl. B60H 1/00; G07B 15/06; H05K 7/20

(52) U.S. Cl. CPC B60H 1/00564; H02J 7/0068; H05K 7/20145; G07B 15/06

(57) ABSTRACT

A heat-exhausting device includes a first inlet through which wind generated as a vehicle travels is taken into a housing; and a circulating path for allowing the wind flowing in from the first inlet to be circulated in the housing. A heat-generating portion of a processing unit which is energized to perform a predetermined process is disposed in contact with an outer wall surface of the circulating path.

### TECHNICAL FIELD

The present invention relates to a heat-exhausting device, a vehicle-mounted device, and a fee machine.

### BACKGROUND ART

Since electronic devices generate heat by energization, heat-exhausting devices are required to prevent the temperature inside sealed housings from becoming excessive. For example, Patent Literature 1 discloses a heat-exhausting device in which wind caused by traveling of a vehicle is used as a device for exhausting heat of a control device mounted on the vehicle.

### CITATION LIST

### Patent Literature

### Patent Literature 1

Japanese Unexamined Patent Application, First Publication No. 2013-103506

### SUMMARY OF INVENTION

### Technical Problem

However, since the heat-exhaust device is attached to an outer side of a housing of the control device in the invention described in Patent Literature 1, a size of the entire device increases. For this reason, a heat-exhaust device having a compact and simple structure has been desired.

### Solution to Problem

According to a first aspect of the present invention, a heat-exhausting device (1A to 1F) includes: a first inlet (11) configured to take wind generated by traveling of vehicle into a housing (2); and a circulating path (10) through which the wind taken from the first inlet (11) is allowed to pass in the housing (2). A heat-generating portion (31A to 31D) of a processing unit (3) configured to perform a predetermined process is disposed when the processing unit (3) is energized in contact with an outer wall surface of the circulating path (10).

Thus, the heat-exhausting device can exhaust heat of the heat-generating portion (cool the heat-generating portion) of the processing unit only with a compact and simple structure having a circulating path inside the housing.

According to a second aspect of the present invention, in the heat-exhausting device (1A to 1F) according to the first aspect, a heat radiating portion (32) attached to the heat-generating portion (31A to 31D) of the processing unit (3) is disposed inside the circulating path (10).

Thus, the heat-exhausting device can directly cool the heat radiating portion by the wind flowing in the circulating path to improve the heat exhaust effect (the cooling effect) of the heat-generating portion.

According to a third aspect of the present invention, in the heat-exhausting device (1B) according to the first or second aspect, a second inlet (13) is configured to take the wind into the housing (2) is provided in the circulating path (10) on a downstream side compared with the first inlet (11).

Thus, since the heat-exhausting device can also take the wind from the second inlet, it is possible to further improve the heat exhaust effect (the cooling effect) of the heat-generating portion by increasing an amount of wind circulating through the circulating path.

According to a fourth aspect of the present invention, in the heat-exhausting device (1B) according to the third aspect, the second inlet (13) is open in an upper surface (21) of the housing (2).

Thus, when the vehicle stops and there is no wind to be generated, the heat-exhausting device can discharge the air (warm air) in the circulating path heated by the heat generated from the heat-generating portion of the processing unit, sunlight, or the like from the second inlet. Therefore, the heat-exhausting device can prevent heat from being retained inside the housing due to an influence of the heat generated from the heat-generating portion of the processing unit, sunlight, or the like while the vehicle stops.

According to a fifth aspect of the present invention, in the heat-exhausting device (1B) according to the third or fourth aspect, a cross-sectional area of the circulating path (10) on the downstream side is larger than a cross-sectional area of the circulating path on an upstream side.

Thus, the heat-exhausting device can keep the pressure in the circulating path substantially constant even when a flow rate in the circulating path increases by the wind taken from the second inlet, and thus it is possible to smoothly circulate the wind by minimizing a decrease in flow velocity.

According to a sixth aspect of the present invention, the heat-exhausting device (1A to 1F) according to any one of the first to fifth aspects further includes: a propeller (41) provided in the circulating path (10); and a battery (43) configured to be charged with electricity by the propeller (41) rotated by the wind.

Thus, while the vehicle is traveling, the heat-exhausting device can rotate the propeller by the wind flowing through the circulating path to store electric power in the battery.

According to a seventh aspect of the present invention, in the heat-exhausting device (1C) according to the first aspect, the battery (43) is configured to supply electric power to the propeller (41) when the rotation of the propeller (41) stops.

Thus, when the vehicle stops and there is no wind to be generated, the heat-exhausting device can rotate the propeller by the electric power stored in the battery to generate an air flow in the circulating path. Therefore, the heat-exhausting device can exhaust the heat of the heat-generating portion even when the vehicle stops.

According to the eighth aspect of the present invention, a vehicle-mounted device (100) includes: the heat-exhausting device (1A to 1D) according to any one of the first to sixth aspects; and the processing unit (3).

Thus, for example, the vehicle-mounted device mounted on the vehicle such as a road maintenance work vehicle can exhaust heat of the heat-generating portion (cool the heat-generating portion) of the processing unit as the vehicle travels.

According to the ninth aspect of the present invention, a fee machine (101) provided on a roadside of a lane includes: the heat-exhausting device (1A to 1D) according to any one of the first to sixth aspects; and the processing unit (3).

Thus, the fee machine can take the wind generated when the vehicle travels in the lane into the housing of the fee machine to exhaust heat of the heat-generating portion (cool the heat-generating portion) of the processing unit.

### Advantageous Effects of Invention

According to the heat-exhausting device, the vehicle-mounted device, and the fee machine associated with any one of the above aspects, it is possible to exhaust heat from the heat-generating portion of the processing unit only with a compact and simple structure.

### BRIEF DESCRIPTION OF DRAWINGS

FIG. 1 is a schematic diagram showing an overall structure of a vehicle-mounted device and a heat-exhausting device according to a first embodiment of the present invention.

FIG. 2 is a perspective view for explaining a structure of the vehicle-mounted device and the heat-exhausting device according to the first embodiment of the present invention.

FIG. 3 is a perspective view for explaining a structure of a vehicle-mounted device and a heat-exhausting device according to a second embodiment of the present invention.

FIG. 4 is a first cross-sectional view of the vehicle-mounted device and the heat-exhausting device according to the second embodiment of the present invention.

FIG. 5 is a second cross-sectional view of the vehicle-mounted device and the heat-exhausting device according to the second embodiment of the present invention.

FIG. 6 is a partially enlarged diagram of the vicinity of a second inlet according to the second embodiment of the present invention.

FIG. 7 is a cross-sectional view of a vehicle-mounted device and a heat-exhausting device according to a third embodiment of the present invention.

FIG. 8 is a cross-sectional view of a vehicle-mounted device and a heat-exhausting device according to a fourth embodiment of the present invention.

FIG. 9 is a perspective view of a fee machine and a heat-exhausting device according to a fifth embodiment of the present invention.

FIG. 10 is a cross-sectional view of the fee machine and the heat-exhausting device according to the fifth embodiment of the present invention.

FIG. 11 is a cross-sectional view of a fee machine and a heat-exhausting device according to a modified example of the fifth embodiment of the present invention.

### DESCRIPTION OF EMBODIMENTS

### First Embodiment

### Structure of Vehicle-Mounted Device and Heat-Exhausting Device

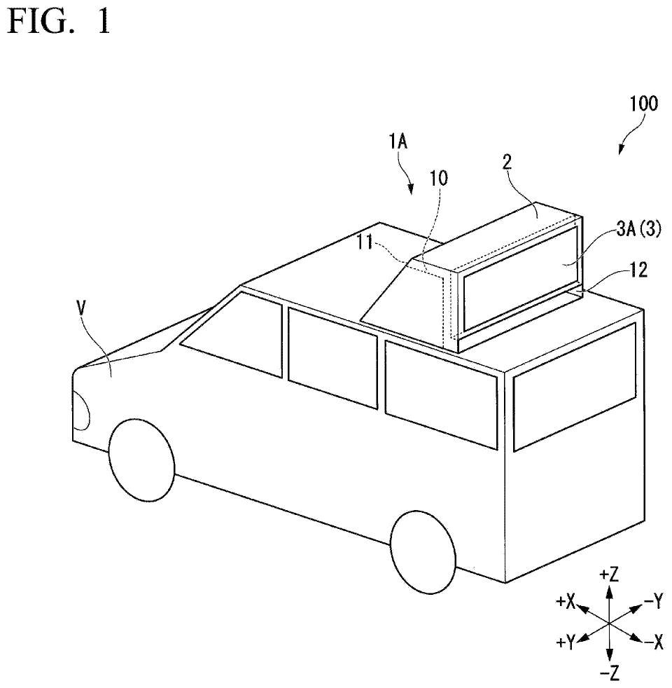

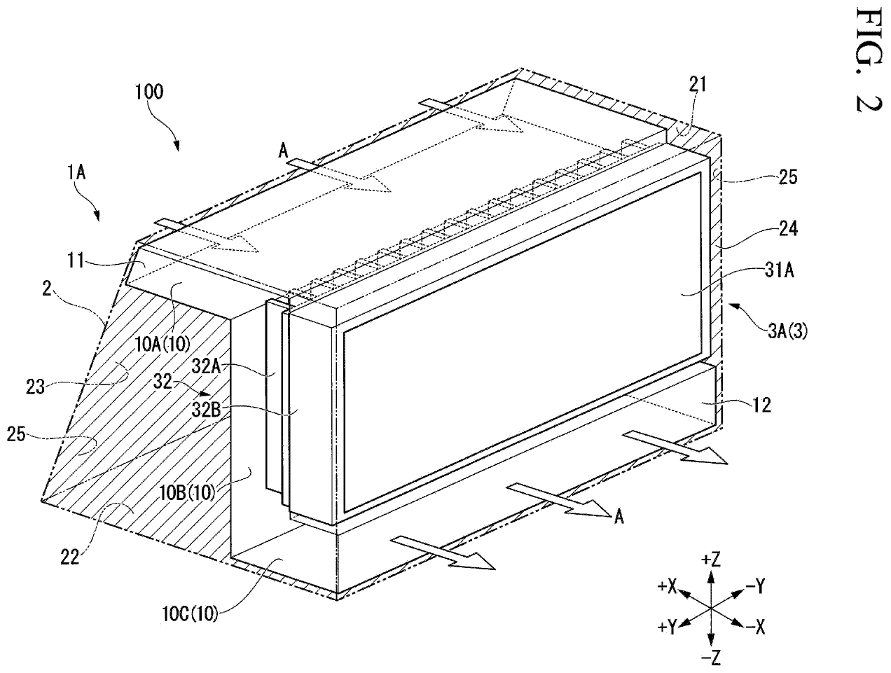

A vehicle-mounted device 100 and a heat-exhausting device 1A according to a first embodiment will be described below with reference to FIGS. 1 and 2.

FIG. 1 is a schematic diagram showing an overall structure of the vehicle-mounted device and the heat-exhausting device according to the first embodiment of the present invention.

FIG. 2 is a perspective view for explaining a structure of the vehicle-mounted device and the heat-exhausting device according to the first embodiment of the present invention.

The vehicle-mounted device 100 is a vehicle-mounted indicator attached to an outer side of a vehicle body of a road maintenance work vehicle (hereinafter referred to as a “vehicle V”) which handles, for example, a traffic accident, a broken vehicle, and a fallen object.

As shown in FIGS. 1 and 2, the vehicle-mounted device 100 includes the heat-exhausting device 1A, a housing 2, and a processing unit 3.

The housing 2 includes the heat-exhausting device 1A and the vehicle-mounted device 100 therein.

As shown in FIG. 2, the housing 2 has an upper surface 21 facing upward (a +Z direction) in a vertical direction, a bottom surface 22 facing downward (a −Z direction) in the vertical direction, a front surface 23 facing in a forward direction (a +X direction) of the vehicle V, a rear surface 24 facing in a rearward direction (a −X direction) of the vehicle V, and a side surface 25 facing in lateral directions (a +Y direction and a −Y direction) of the vehicle V.

The processing unit 3 is energized to perform a predetermined process. For example, the processing unit 3 in the present embodiment is a display unit 3A which performs processing for displaying characters, figures, and the like by causing a plurality of light emitting diodes (LEDs) to be energized to emit light. As shown in FIG. 2, the display unit 3A includes a display portion 31A (a heat-generating portion) and a heat radiating portion 32.

The display portion 31A is a board having a plurality of LEDs arranged thereon, is exposed to the outside from the rear surface 24 of the housing 2, and is disposed to face the rear side (the −X direction) of the vehicle V. The display portion 31A emits light in a predetermined pattern in accordance with a command from a control device (not shown) so that a message (for example, “working,” “reducing speed,” or the like) associated with maintenance work is displayed to a vehicle traveling behind the vehicle V. Furthermore, the display portion 31A is an aspect of a heat-generating portion which causes a LED to emit light to generate heat when energized.

In another embodiment, the display portion 31A may be disposed to face the lateral direction (the +Y direction or the −Y direction) of the vehicle V.

The heat radiating portion 32 is a heat sink which radiates heat generated from the display portion 31A. As shown in FIG. 2, the heat radiating portion 32 has a plurality of fins 32A and a baseportion 32B connecting the fins 32A. Each of the fins 32A is a flat metal piece which protrudes from the base portion 32B attached to a rear surface (a surface facing a +X side in FIG. 2) of the display portion 31A and extends in a height direction (the ±Z direction) of the display portion 31A. Furthermore, the plurality of fins 32A are disposed at predetermined intervals in a width direction (the ±Y direction) of the display portion 31A.

The heat-exhausting device 1A is provided inside the housing 2 of the vehicle-mounted device 100. The heat-exhausting device 1A is a device for exhausting heat from the heat radiating portion 32 of the processing unit 3 (the display unit 3A).

As shown in FIGS. 1 and 2, the heat-exhausting device 1A includes a circulating path 10, a first inlet 11, and an outlet 12.

The first inlet 11 is open in the front surface 23 of the housing 2 to face the forward direction (the +X direction) of the vehicle V. Thus, the wind A generated by traveling of the vehicle V is taken into the housing 2 through the first inlet 11. Although FIG. 2 shows an example in which one first inlet 11 is open, the present invention is not limited thereto. A plurality of first inlets 11 may be open in the front surface 23 of the housing 2. Furthermore, although FIG. 2 shows an example in which the first inlet 11 has a rectangular shape, the present invention is not limited thereto. The first inlet 11 may have another shape such as a circular shape.

The circulating path 10 allows the wind A taken from the first inlet 11 to flow through the housing 2.

As shown in FIG. 2, the circulating path 10 according to the embodiment has structures including an inlet flow path 10A connected to the first inlet 11 and extending to the rear side (the −X side) of the vehicle V along the upper surface 21 of the housing 2, an intermediate flow path 10B extending in a downward direction (a −Z side) in the vertical direction along the rear surface of the display portion 31A of the display unit 3A, and an outlet flow path 10C extending to the rear side (a −X side) of the vehicle V along the bottom surface 22 of the housing 2 and connected to the outlet 12.

Also, the rear surface of the display portion 31A of the display unit 3A is disposed in contact with the rear side (the −X side) of an outer wall surface of the intermediate flow path 10B. In the embodiment, as shown in FIG. 2, the heat radiating portion 32 of the display unit 3A is disposed inside the intermediate flow path 10B. For example, the base portion 32B of the heat radiating portion 32 is attached to the rear surface of the display portion 31A by being screwed to sandwich the rear side (the −X side) of the outer wall surface of the intermediate flow path 10B. Furthermore, in this case, the heat radiating portion 32 is disposed so that a direction in which the fins 32A extend (the ±Z direction) is directed along a direction in which the wind A in the intermediate flow path 10B flows (the −Z direction). Thus, the wind A can smoothly flow between neighboring fins 32A.

The wind A flowing inside the circulating path 10 is discharged from the outlet flow path 10C to the outside of the housing 2 through the outlet 12.

Although FIG. 2 shows an example in which one outlet 12 is open, the present invention is not limited thereto. A plurality of outlets 12 may be open in the rear surface 24 of the housing 2. Furthermore, although FIG. 2 shows an example in which the outlet 12 has a rectangular shape, the present invention is not limited thereto. The outlet 12 may have another shape such as a circular shape.

Also, although FIG. 2 shows an example in which the first inlet 11 is open over the entire width direction (the ±Y direction) of the housing 2 on an upper side (the +Z side) of the front surface 23 of the housing 2 and the outlet 12 is open over the entire width direction (the ±Y direction) of the housing 2 on a lower side (the −Z side) of the rear surface 24 of the housing 2, the present invention is not limited thereto.

For example, the disposition of the first inlet 11 and the outlet 12 may be upside down. That is to say, the first inlet 11 may have a structure to open over the entire width direction (the ±Y direction) of the housing 2 on the lower side (the −Z side) of the front surface 23 of the housing 2 and outlet 12 may have a structure to open over the entire width direction (the ±Y direction) of the housing 2 on the upper side (the +Z side) of the rear surface 24 of the housing 2. In this case, the inlet flow path 10A of the circulating path 10 extends to the rear side (the −X direction) of the vehicle V along the bottom surface 22 of the housing 2. The intermediate flow path 10B extends to an upper side (the +Z direction) in the vertical direction along the rear surface of the display portion 31A of the display unit 3A. The outlet flow path 10C extends to the rear side (the −X direction) of the vehicle V along the upper surface 21 of the housing 2 and is connected to the outlet 12.

Also, for example, the first inlet 11 may be configured to be open toward the vertical direction (the ±Z direction) on one side (the +Y side) of the front surface 23 of the housing 2 in the width direction and the outlet 12 may be configured to be open toward the vertical direction (the ±Z direction) on the other side (the −Y side) of the rear surface 24 of the housing 2 in the width direction. In this case, the inlet flow path 10A of the circulating path 10 extends to the rear side (the −X direction) of the vehicle V along the side surface 25 and the bottom surface 22 on one side (the +Y side) of the housing 2 in the width direction: The intermediate flow path 10B extends to the other side (the −Y direction) in the width direction along the rear surface of the display portion 31A of the display unit 3A. The outlet flow path 10C extends to the rear side (the −X direction) of the vehicle V along the side surface 25 and the upper surface 21 on the other side (the −Y side) of the housing 2 in the width direction and connected to the outlet 12. In this case, the heat radiating portion 32 of the display unit 3A is disposed so that the plurality of fins 32A extending in the width direction (the ±Y direction) of the display portion 31A are disposed at predetermined intervals in the height direction (the ±Z direction) of the display portion 31A. Furthermore, the first inlet 11 may be disposed on the other side (the +Y side) in the width direction and the outlet 12 may be disposed on one side (the −Y side) in the width direction. In this case, the disposition of the inlet flow path 10A and the outlet flow path 10C is also changed in the same manner.

### Function of Heat-Exhausting Device

When the vehicle V having the vehicle-mounted device 100 attached thereto starts traveling forward (in the +X direction), as shown in FIG. 2, the wind A generated by traveling of the vehicle V flows from the first inlet 11 of the heat-exhausting device 1A into the circulating path 10 inside the housing 2.

The wind A flowing into the circulating path 10 flows to the rear side (the −X direction) of the vehicle V along the inlet flow path 10A. Furthermore, the wind A is deflected downward (the −Z direction) in the vertical direction and flows into the intermediate flow path 10B when colliding with a wall surface on the rear side of the circulating path 10.

Subsequently, as the wind A flows downward (the −Z direction) in the vertical direction along the intermediate, flow path 10B, the wall surface of the intermediate flow path 10B is cooled. Thus, heat exchange is performed between the display portion 31A of the display unit 3A and the wall surface of the intermediate flow path 10B and the display portion 31A of the display unit 3A is cooled.

Also, as shown in FIG. 2, in the present embodiment, the heat radiating portion 32 of the display unit 3A is disposed inside the intermediate flow path. For this reason, the wind A directly cools the heat radiating portion 32 in the intermediate flow path 10B. Thus, since heat exchange is also performed between the display portion 31A and the heat radiating portion 32, the display portion 31A is cooled more efficiently. Furthermore, the heat radiating portion 32 has the fins 32A disposed along a flow direction of the intermediate flow path 10B (the −Z direction). For this reason, the wind A can smoothly flow along surfaces of the fins 32A of the heat radiating portion 32 without being obstructed by the fins 32A. In addition, since a surface area of the heat radiating portion 32 coming into contact with the wind A increases due to the fins 32A, it is possible to improve the cooling effect using the wind A.

Subsequently, the wind A is deflected to the rear side (the −X direction) of the vehicle V and flows into the outlet flow path 10C when colliding with the wall surface on the lower side (the −Z side) of the circulating path 10. The wind A flows rearward along the outlet flow path 10C and is discharged from the outlet 12 to the outside of the housing 2.

### Effect of Heat-Exhausting Device

As described above, the heat-exhausting device 1A according to the present embodiment includes the first inlet 11 configured to take the wind A generated by traveling of the vehicle V into the housing 2 and the circulating path 10 for allowing the wind A taken from the first inlet 11 to flow through the housing 2. The display portion 31A of the display unit 3A (the heat-generating portion of the processing unit 3) configured to perform a predetermined process when the display unit 3A is energized is disposed in contact with the outer wall surface of the circulating path 10.

Thus, the heat-exhausting device 1A can exhaust heat from or cool the display portion 31A of the display unit 3A only with a compact and simple structure having the circulating path 10 inside the housing 2.

Also, the heat radiating portion 32 attached to the display portion 31A of the display unit 3A is disposed inside the circulating path 10.

Thus, the heat-exhausting device 1A can directly cool the heat radiating portion 32 using the wind A flowing in the circulating path 10 to improve the heat exhaust effect (the cooling effect) of the display portion 31A. Furthermore, only the heat radiating portion 32 is disposed in the circulating path 10 and the display portion 31A of the processing unit is disposed outside the circulating path 10. Thus, even when dust, rainwater, or the like enters the circulating path 10 together with the wind A, it is possible to minimize an influence on a precision machine such as the display portion 31A.

Furthermore, the vehicle-mounted device 100 according to the present embodiment includes the heat-exhausting device 1A and the display unit 3A (the processing unit 3).

Thus, for example, when the vehicle-mounted device 100 mounted on the vehicle V such as a road maintenance work vehicle can exhaust heat from or cool the display portion 31A (the heat-generating portion of the processing unit 3) as the vehicle V travels.

### Second Embodiment

### Structure of Vehicle-Mounted Device and Heat-Exhausting Device

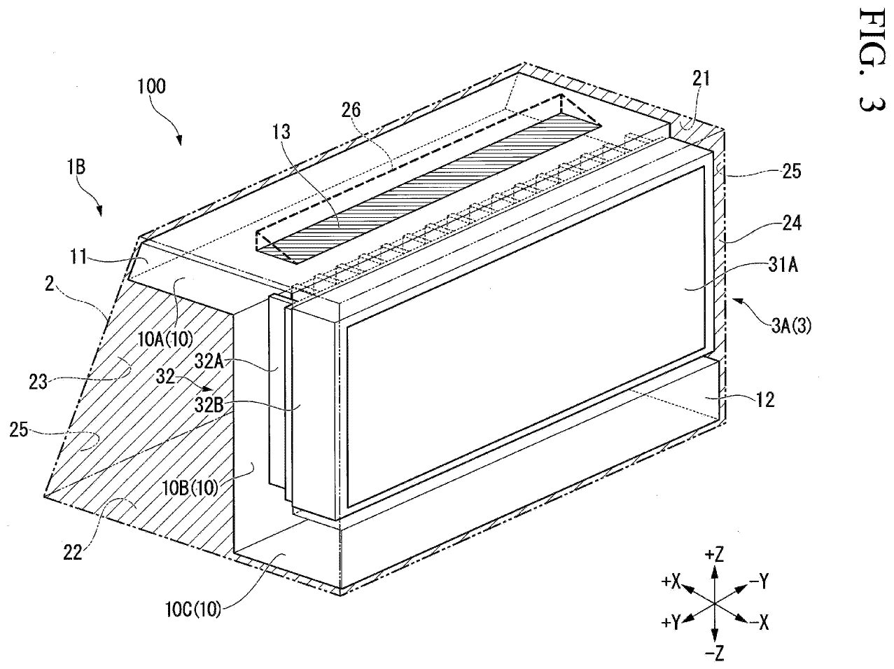

A vehicle-mounted device 100 and a heat-exhausting device 1B according to a second embodiment will be described below with reference to FIGS. 3 to 6. Differences between the second embodiment and the first embodiment described above will be mainly described, structural elements in the second embodiment that are the same as those in the first embodiment will be denoted by the same reference numerals, and detailed description thereof will be omitted.

FIG. 3 is a perspective view for explaining a structure of the vehicle-mounted device and the heat-exhausting device according to the second embodiment of the present invention.

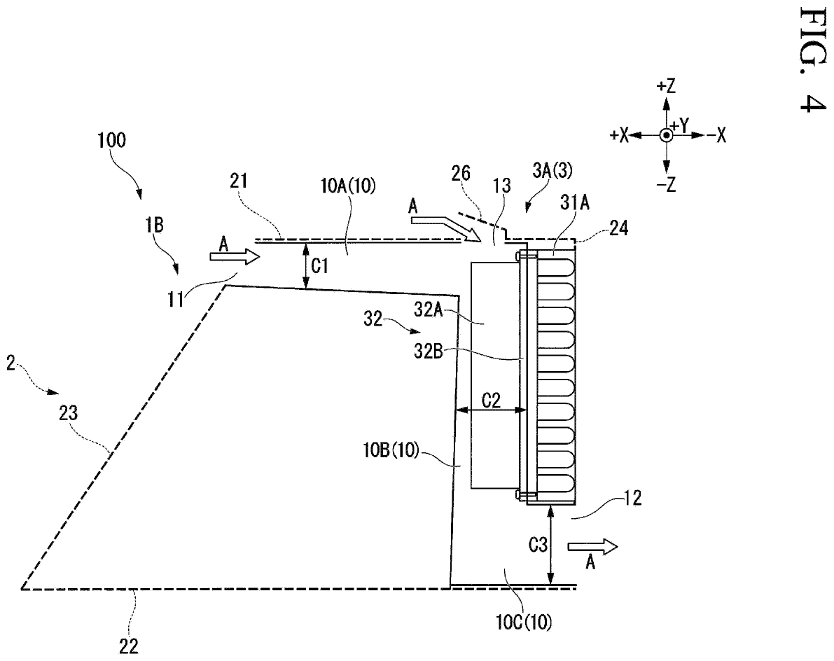

FIG. 4 is a first cross-sectional view of the vehicle-mounted device and the heat-exhausting device according to the second embodiment of the present invention.

As shown in FIGS. 3 and 4, in a circulating path 10 according to the present embodiment, a second inlet 13 for allowing the wind A to be taken into a housing 2 is provided on a downstream side compared with a first inlet 11.

To be specific, as shown in FIGS. 3 and 4, the second inlet 13 is open in a rectangular shape in the circulating path 10 and an upper surface 21 of the housing 2 and allows the wind A to be taken from the outside of the housing 2 into the circulating path 10. Furthermore, the second inlet 13 has a guide portion 26 protruding upward (the +Z direction) in the vertical direction of the second inlet 13 and toward the front (the +X direction) of the vehicle V and provided in the upper surface 21 of the housing 2. Thus, the wind A is easily taken into the second inlet 13 by being guided by the guide portion 26. In addition, the guide portion 26 can prevent, for example, the inside of the circulating path 10 from being irradiated with sunlight which is one of the causes for raising a temperature inside the circulating path 10.

Although FIG. 3 shows an example in which only one second inlet 13 which is open toward the upper surface 21 of the housing 2 is provided, the present invention is not limited thereto. In another embodiment, two or more second inlets 13 may be provided in the upper surface 21 of the housing 2. In this case, there are no restrictions on the disposition of a plurality of second inlets 13 provided in the upper surface 21 of the housing 2, for example, the plurality of second inlets 13 may be disposed to be aligned in a forward/rearward direction (the ±X direction) or a width direction (the ±Y direction) of the vehicle V or may be disposed in a staggered manner.

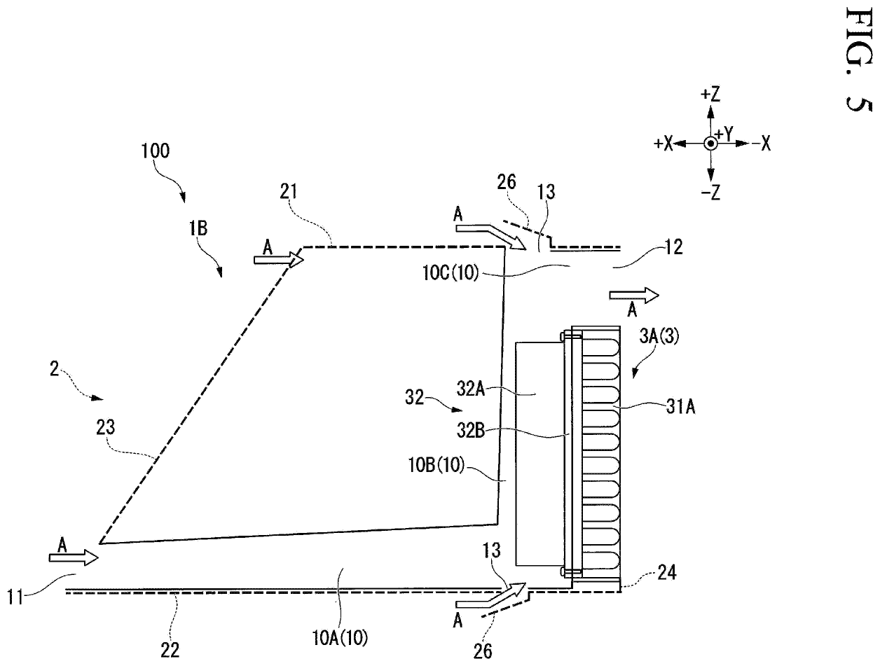

FIG. 5 is a second cross-sectional view of the vehicle-mounted device and the heat-exhausting device according to the second embodiment of the present invention.

Also, for example, when there is a gap between an upper surface of a vehicle body of the vehicle V and a bottom surface 22 of the housing 2, and as shown in FIG. 5, when the inlet flow path 10A is configured to be disposed along the bottom surface 22 of the housing 2, the second inlet 13 may be further provided in the bottom surface 22 of the housing 2. In this case, the guide portion 26 protruding downward (the −Z direction) in the vertical direction of the second inlet 13 and toward the front (the +X direction) of the vehicle V may be formed on a position of the bottom surface 22 of the housing 2 corresponding to the second inlet 13.

Also, for example, when a sunroof is provided in an upper surface of a vehicle body of the vehicle V, and as shown in FIG. 5, when the inlet flow path 10A is disposed along the bottom surface 22 of the housing 2, the second inlet 13 may be provided in the bottom surface 22 of the housing 2 in the inlet flow path 10A so as to be located above the sunroof. Therefore, when air conditioning is used inside the vehicle V, cold air inside the vehicle flows from the second inlet 13 provided in the bottom surface 22 of the housing 2 into the housing 2. Thus, it is possible to further improve the heat exhaust effect (the cooling effect) of the display portion 31A of the display unit 3A.

Although FIG. 4 shows an example in which only one second inlet 13 which is open in the bottom surface 22 of the housing 2 is provided, the present invention is not limited thereto. In another embodiment, two or more second inlets 13 may be provided in the bottom surface 22 of the housing 2. in this case, there are no restrictions on the disposition of the plurality of second inlets 13 provided in the bottom surface 22 of the housing 2. For example, the plurality of second inlets 13 may be disposed to be aligned in the forward/rearward direction (the ±X direction) or the width direction (the ±Y direction) of the vehicle V or disposed in a staggered manner.

The second inlet 13 may be provided only in the upper surface 21 of the housing 2 as shown in FIG. 3 and the second inlets 13 may be provided in both of the upper surface 21 and the bottom surface 22 of the housing 2 as shown in FIG. 4. Furthermore, in another embodiment, the second inlet 13 may be provided in the side surface 25 of the housing 2.

Also, as shown in FIG. 4, a cross-sectional area of the circulating path 10 of the heat-exhausting device 1B according to the present embodiment on the downstream side is larger than that of on the upstream side. For this reason, even when a flow rate in the circulating path 10 increases by taking the wind A from the second inlet 13, it is possible to prevent the pressure in the downstream side of the circulating path 10 from being lower than the pressure in the upstream side of the circulating path 10.

To be specific, as shown in FIG. 4, the intermediate flow path 10B has a cross-sectional area C2 larger than a cross-sectional area C1 of the inlet flow path 10A. The outlet flow path 10C has a cross-sectional area C3 larger than the cross-sectional area C2 of the intermediate flow path 10B.

Furthermore, as shown in FIG. 4, the inlet flow path 10A, the intermediate flow path 10B, and the outlet flow path 10C may be formed so that the cross-sectional areas thereof gradually increase toward the downstream side.

### Function of Heat-Exhausting Device

When the vehicle V having the vehicle-mounted device 100 attached thereto starts traveling forward (in the +X direction), as shown in FIG. 4, the wind A generated by traveling of the vehicle V flows into the circulating path 10 inside the housing 2 from the first inlet 11 and the second inlet 13 of the heat exhausting device 1B.

Since the wind A flows from a plurality of places into the circulating path 10 in the present embodiment, a flow rate flowing inside the circulating path 10 increases as compared with the first embodiment. However, since the circulating path 10 according to the present embodiment is formed so that the cross-sectional area of the circulating path 10 on the downstream side is larger than a cross-sectional area of the circulating path 10 on the upstream side, the pressure in the circulating path 10 is kept substantially constant. Thus, the wind A can smoothly flow in the circulating path 10 without reducing the speed.

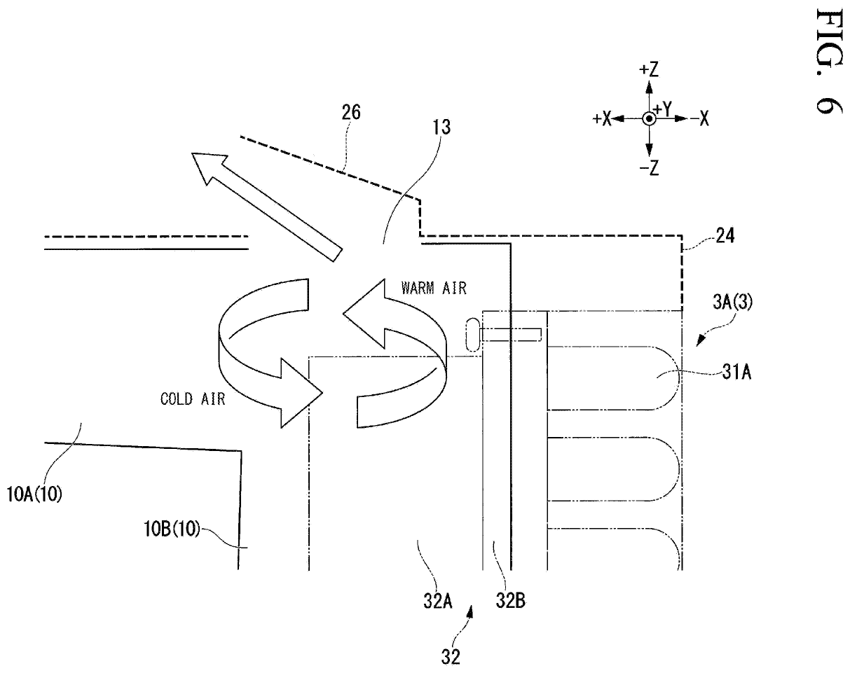

FIG. 6 is a partially enlarged diagram of the vicinity of a second inlet according to the second embodiment of the present invention.

As shown in FIG. 6, when the vehicle V stops and the wind A is not generated, convection occurs in the circulating path 10 by the heat generated from the display portion 31A of the display unit 3A. Thus, the air (warm air) in the circulating path 10 heated by the heat generated from the display portion 31A of the display unit 3A rises upward (the +Z direction) in the vertical direction and is discharged from the second inlet 13 to the outside of the housing 2.

### Effect of Heat-Exhausting Device

As described above, in the heat-exhausting device 1B according to the embodiment, the second inlet 13 configured to take the wind A into the housing 2 is provided on the downstream side of the circulating path 10 compared with the first inlet 11.

Thus, since the heat-exhausting device 1B can also take the wind A from the second inlet 13, it is possible to further improve the heat exhaust effect (the cooling effect) of the heat-generating portion by increasing an amount of wind flowing through the circulating path 10.

Also, the second inlet 13 is open in the upper surface 21 of the housing 2. Thus, when the vehicle V stops and there is no wind A to be generated, the heat-exhausting device 1B can discharge the air (warm air) in the circulating path 10 heated by the heat generated from the display portion 31A of the display unit 3A, sunlight, or the like from the second inlet 13. Therefore, the heat-exhausting device 1B prevents heat from being retained inside the housing 2 due to an influence of the heat generated from the display portion 31A of the display unit 3A, sunlight, or the like while the vehicle V stops.

Furthermore, a cross-sectional area of the circulating path 10 on the downstream side is larger than a cross-sectional area of the circulating path 10 on the upstream side.

Thus, since the heat-exhausting device 1B can keep the pressure in the circulating path 10 substantially constant even when a flow rate in the circulating path 10 increases by the wind A taken from the second inlet 13, it is possible to smoothly circulate the wind A by minimizing a decrease in flow velocity.

### Third Embodiment

### Structure of Vehicle-Mounted Device and Heat-Exhausting Device

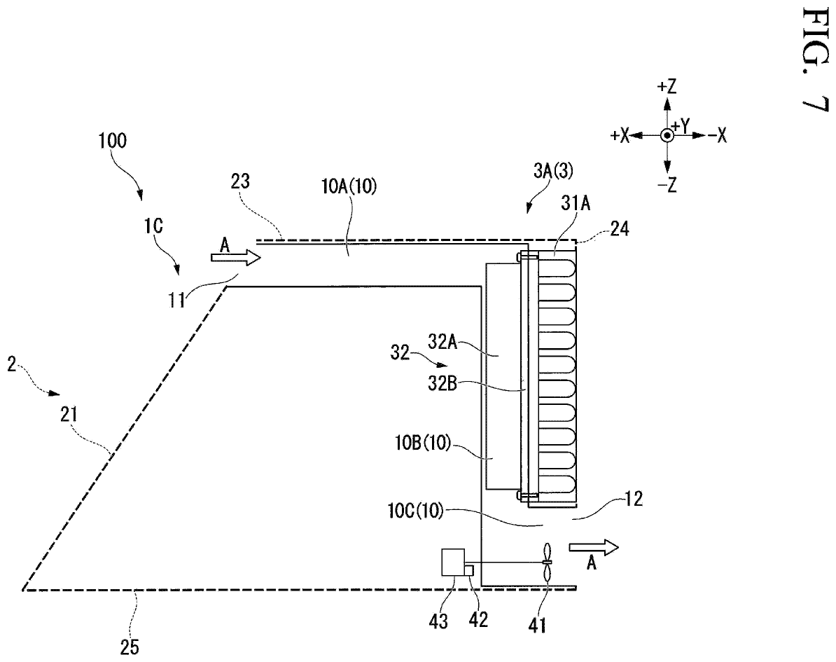

A vehicle-mounted device 100 and a heat-exhausting device 1C according to a third embodiment will be described below with reference to FIG. 7. Differences between the third embodiment and the first and second embodiments described above will be mainly described, structural elements in the third embodiment that are the same as those in the first and third embodiments will be denoted by the same reference numerals, and detailed description thereof will be omitted.

FIG. 7 is a cross-sectional view of a vehicle-mounted device and a heat-exhausting device according to the third embodiment of the present invention.

As shown in FIG. 7, the heat-exhausting device 1C according to the embodiment further includes a propeller 41, a sensor 42, and a battery 43.

The propeller 41 is provided at an arbitrary position inside a circulating path 10. Although the propeller 41 may be provided at any of the inlet flow path 10A, the intermediate flow path 10B, and the outlet flow path 10C, it is preferable that the propeller 41 be provided in the vicinity of the outlet 12 in the outlet flow path 10C as shown in FIG. 7. The propeller 41 rotates by the wind A flowing inside the circulating path 10 while a vehicle V is traveling.

The sensor 42 is, for example, a rotary encoder which detects the presence or absence of the rotation of the propeller 41.

The battery 43 is charged with electricity by the propeller 41 rotated by the wind A. Furthermore, when the sensor 42 detects that the propeller 41 is not rotating, the battery 43 supplies the stored electric power to the propeller 41 so that the propeller 41 rotates.

### Function of Heat-Exhausting Device

When the vehicle V having the vehicle-mounted device 100 attached thereto starts traveling forward (the +X direction), as shown in FIG. 7, the wind A generated as the vehicle V travels flows from a first inlet 11 of a heat-exhausting device 1B into the circulating path 10 inside a housing 2. The propeller 41 then rotates by receiving the wind A flowing through the circulating path 10. As the propeller 41 rotates, electric power is stored in the battery 43.

Also, when the vehicle V stops and there is no wind A to be generated, the rotation of the propeller 41 stops. When the sensor 42 detects that the rotation of the propeller 41 has stopped, the battery 43 supplies the stored electric power to the propeller 41 so that the propeller 41 rotates. When the propeller 41 rotates, it is possible to cause the air in the circulating path 10 to flow by generating an air flow inside the circulating path 10.

The battery 43 according to the present embodiment stops the supplying of electric power to the propeller 41 after a predetermined time (for example, 5 minutes) has elapsed. At this time, when the vehicle V starts traveling again and the wind A is taken into the circulating path 10, the propeller 41 continues to rotate by the wind A. In this case, since the sensor 42 detects that the propeller 41 is rotating, the battery 43 does not supply electric power to the propeller 41.

On the other hand, when the vehicle V remains stopped, the rotation of the propeller 41 also remains stopped and the sensor 42 detects that the propeller 41 is stopped. Thus, the battery 43 starts the supplying of electric power to the propeller 41 again.

### Effect of Heat-Exhausting Device

As described above, the heat-exhausting device 1C according to the present embodiment further includes the propeller 41 provided on the circulating path 10 and the battery 43 configured to be charged with electricity by a rotation of the propeller 41.

Thus, the heat-exhausting device 1C can cause the propeller 41 to rotate using the wind A flowing through the circulating path 10 when the vehicle is traveling and electric power to be stored in the battery 43.

Also, the battery 43 supplies electric power to the propeller 41 when the rotation of the propeller 41 stops.

Thus, the heat-exhausting device 1C can cause the propeller 41 to rotate using the electric power stored in the battery 43 when the vehicle V stops and there is no wind to be generated and generate an air flow in the circulating path 10. Therefore, the heat-exhausting device 1C can exhaust heat of the display portion 31A of the display unit 3A even when the vehicle V stops.

Furthermore, since the propeller 41 rotates using the electric power stored as the vehicle V travels while the vehicle V stops in this way, it is possible to minimize an increase in power consumption of the heat-exhausting device 1C by adding the propeller 41.

In addition, the battery 43 supplies electric power to the propeller 41 for a predetermined time after the sensor 42 detects that the rotation of the propeller 41 has stopped.

Thus, the battery 43 can periodically generate an air flow while the vehicle V stops. Moreover, since the battery 43 stops the supplying of electric power after a predetermined time has elapsed even when the vehicle V starts traveling again while the battery 43 supplies electric power to the propeller 41, for example, while the battery 43 is supplying electric power to the propeller 41, it is possible to minimize a period during which unnecessary electric power is supplied to the propeller 41 to a predetermined time or less.

The circulating path 10 of the heat-exhausting device 1C according to the present embodiment may have a structure in which the second inlet 13 is provided and the cross-sectional area of the downstream side of the circulating path 10 is larger than the upstream side, in the same way as the second embodiment.

### Fourth Embodiment

### Structure of Vehicle-Mounted Device and Heat-Exhausting Device

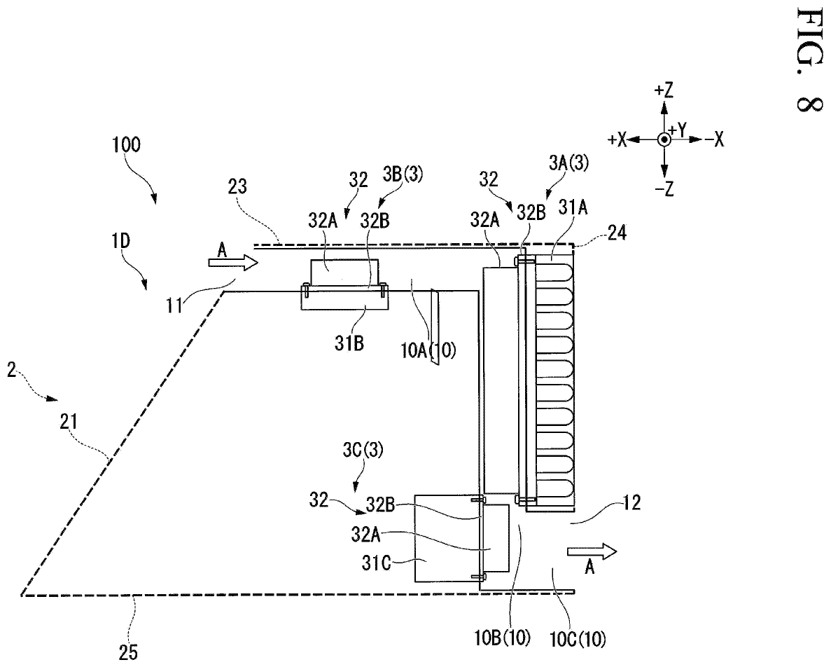

A vehicle-mounted device 100 and a heat-exhausting device 1D according to a fourth embodiment will be described below with reference to FIG. 8. Differences between the fourth embodiment and the first to third embodiments described above will be mainly described, structural elements in the fourth embodiment that are the same as those in the first to third embodiments will be denoted by the same reference numerals, and detailed description thereof will be omitted.

FIG. 8 is a cross-sectional view of the vehicle-mounted device and the heat-exhausting device according to the fourth embodiment of the present invention. As shown in FIG. 8, the vehicle-mounted device 100 according to the embodiment includes a plurality of processing units 3. For example, the vehicle-mounted device 100 includes a substrate 3B and a power supply unit 3C in addition to the display unit 3A as the processing units 3.

The substrate 3B performs a process to control the vehicle-mounted device 100 (for example, the control of the display unit 3A or the like) when the substrate 3B is energized. The substrate 3B includes a CPU 31B which is a heat-generating portion and a heat radiating portion 32.

The power supply unit 3C performs a process to supply electric power to each unit of the vehicle-mounted device 100 when the power supply unit 3C is energized. The power supply unit 3C includes a power supply portion 31C which is a heat-generating portion and the heat radiating portion 32.

A functional structure of the substrate 3B and the heat radiating portion 32 of the power supply unit 3C has the same as that of the display unit 3A.

Although FIG. 8 shows an example in which the vehicle-mounted device 100 includes the three processing units 3, the present invention is not limited thereto. The vehicle-mounted device 100 may include two processing units 3 or four or more processing units 3.

Also, a display portion 31A of a display unit 3A, a CPU 31B of a substrate 3B, and a power supply portion 31C of a power supply unit 3C are disposed in contact with the outer wall surface of the circulating path 10. For example, as shown in FIG. 8, the CPU 31B of the substrate 3B is disposed to be in contact with an outer wall surface on a lower side (the −Z side) of an inlet flow path 10A. Furthermore, the power supply portion 31C of the power supply unit 3C is disposed to be in contact with an outer wall surface on a front side (the +X side) of the intermediate flow path 10B. The disposition of the display unit 3A, the substrate 3B, and the power supply unit 3C shown in FIG. 8 is an example and can be arbitrarily changed in accordance with the structure of the vehicle-mounted device 100.

The heat radiating portions 32 of the display unit 3A, the substrate 3B, and the power supply unit 3C are disposed inside the circulating path 10 as in the first embodiment. In this case, the heat radiating portions 32 are disposed so that an extending direction of fins 32A included in the heat radiating portion 32 of each processing unit 3 coincides to a direction in which the wind A flows in order to prevent the flowing of the wind A from being obstructed by the fins 32A. For example, the substrate 3B is disposed so that the extending direction of the fins 32A coincides the direction (the −X direction) in which the wind A flows in the inlet flow path 10A. Furthermore, the heat radiating portions 32 are disposed so that the extending direction of the fins 32A coincides the direction (the −Z direction) in which the wind A flows in the intermediate flow path 10B as in the power supply unit 3C.

### Effect of Heat-Exhausting Device

As described above, in the heat-exhausting device 1D according to the present embodiment, the heat-generating portions (the display portion 31A, the CPU 31B, and the power supply portion 31C) of the plurality of processing units 3 (the display unit 3A, the substrate 3B, and the power supply unit 3C) are disposed in contact with the outer wall surface of the circulating path 10.

Thus, the heat-exhausting device 1D can simultaneously exhaust heat of or cool the heat-generating portion of the plurality processing units 3 by means of one flow circulating path 10.

The circulating path 10 of the heat-exhausting device 1D according to the present embodiment may have a structure in which the second inlet 13 is provided and the cross-sectional area of the downstream side of the circulating path 10 is larger than that of the upstream side, in the same way as the second embodiment. Furthermore, the circulating path 10 of the heat-exhausting device 1D according to the present embodiment may further include the propeller 41, the sensor 42, and the battery 43, in the same way as the third embodiment.

### Fifth Embodiment

### Structure of Fee Machine and Heat-Exhausting Device

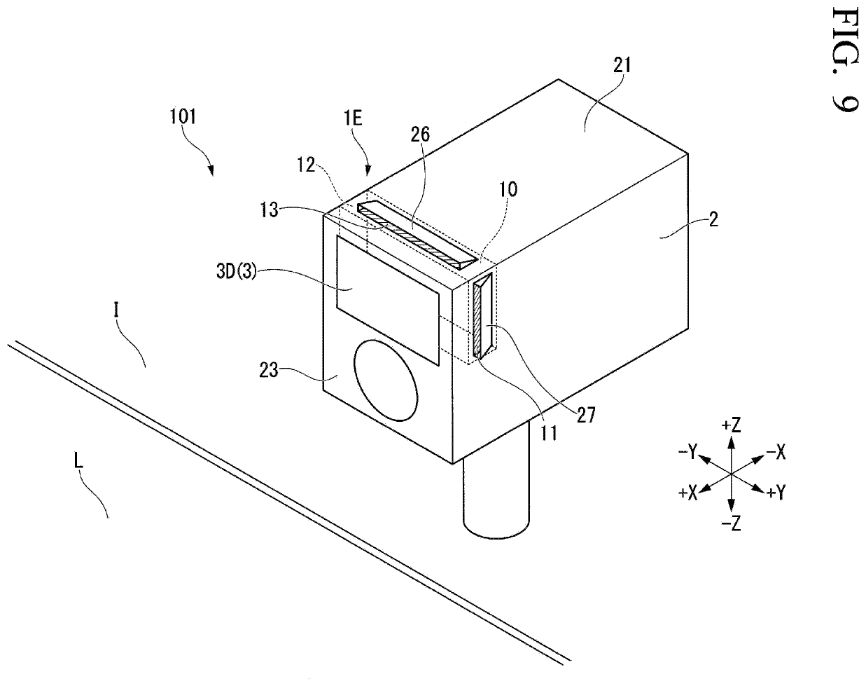

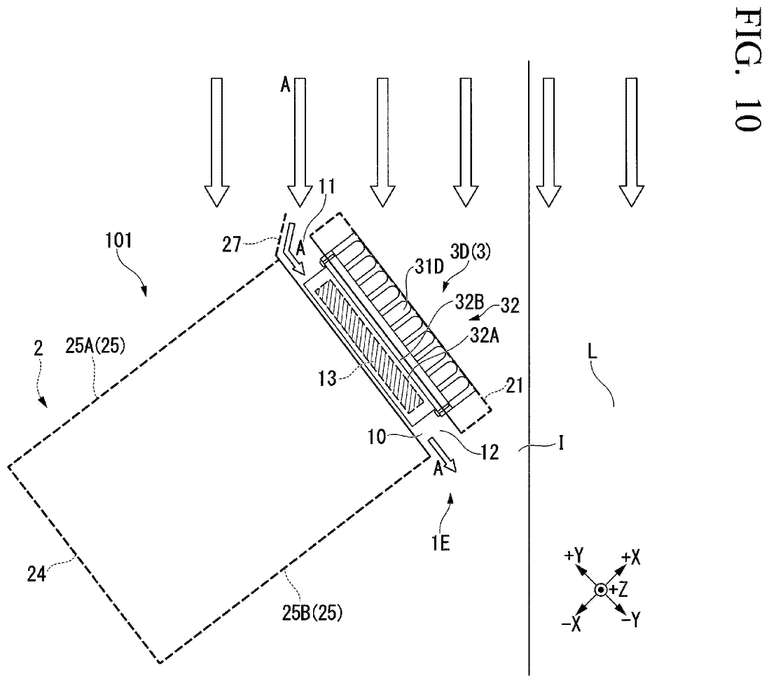

A fee machine 101 and a heat-exhausting device 1E according to a fifth embodiment will be described below with reference to FIGS. 9 and 10. Differences between the fifth embodiment and the first to fourth embodiments described above will be mainly described, structural elements in the fifth embodiment that are the same as those in the first to fourth embodiments will be denoted by the same reference numerals, and detailed description thereof will be omitted.

FIG. 9 is a perspective view of the fee machine and the heat-exhausting device according to the fifth embodiment of the present invention.

FIG. 10 is a cross-sectional view of the fee machine and the heat-exhausting device according to the fifth embodiment of the present invention.

The fee machine 101 is one of a group of devices which performs a toll collection process for collecting usage charges from a vehicle V traveling in a lane L at an entrance tollbooth or an exit tollbooth on a toll road. For example, as shown in FIG. 9, the fee machine 101 according to the present embodiment is a license plate reading device for photographing a license plate of the vehicle V and is installed on an island provided on a road side of the lane L. Furthermore, in the embodiment, the vehicle V is not limited to a road maintenance work vehicle and also includes other vehicles such as a vehicle in which a toll road user gets and emergency vehicles.

As shown in FIG. 10, the fee machine 101 according to the present embodiment includes a lighting unit 3D as the processing unit 3.

The lighting unit 3D performs, when the license plate of the vehicle V traveling in the lane L is photographed, a process of irradiating a region in which the license plate is located with light so that an image of the license plate can be clearly photographed. The lighting unit 3D includes a light emitting unit 31D which is a heat-generating portion and a heat radiating portion 32. The light emitting unit 31D is a board on which a plurality of LEDs are arranged and performs the irradiation of light toward the outside of a housing 2 through a window material provided on a front surface 23 of the housing 2. Furthermore, the light emitting unit 31D is disposed to be directed to a region in which the license plate of the vehicle V is located.

As shown in FIGS. 9 and 10, the heat-exhausting device 1E according to the present embodiment includes a circulating path 10, a first inlet 11, and an outlet 12.

The first inlet 11 is open in a side surface 25A (a side surface 25A on the +Y side) of the housing 2 facing a rear side in a traveling direction of the vehicle V. Furthermore, the first inlet 11 has a rib 27 extending toward the rear side (the +Y side and the +X side) in the traveling direction of the vehicle V.

The circulating path 10 extends in the width direction (the ±Y direction) of the housing 2. The rear surface of the light emitting unit 31D is disposed in contact with the outer wall surface of the circulating path 10 on the front side (the +X side). Furthermore, the heat radiating portion 32 of the lighting unit 3D is disposed inside the circulating path 10. The heat radiating portion 32 is disposed so that an extending direction of the fins 32A (the ±Y direction) coincides the direction in which the wind A flows (the −Y direction) in the circulating path 10.

The outlet 12 is open in the side surface 25B (the side surface 25B on the −Y side) of the housing 2 facing a front side in the travel direction of the vehicle and the wind A flowing inside the circulating path 10 is discharged from the outlet 12 to the outside of the housing 2.

Also, as shown in FIGS. 9 and 10, the second inlet 13 through which the wind A is taken into the housing 2 may be provided in the circulating path 10 on the downstream side compared with the first inlet 11. In this case, similar to the second embodiment, the guide portion 26 protruding upward (the +Z direction) in the vertical direction of the second inlet 13 and toward the front surface 23 side (the +X side) of the housing 2 is formed at a position of the upper surface 21 of the housing 2 corresponding to the second inlet 13. Thus, the wind A is easily taken into the second inlet 13 by being guided by the guide portion 26. In addition, the guide portion 26 can prevent a temperature inside the circulating path 10 from rising due to the irradiation of sunlight into the circulating path 10.

### Function of Heat-Exhausting Device

When the vehicle V travels in the lane L, as shown in FIG. 10, the wind A toward the front side in the travel direction of the vehicle V is generated as the vehicle V travels. Thus, the wind A flows from the first inlet 11 of the heat-exhausting device 1E into the circulating path 10 inside the housing 2. The wind A is guided by the rib 27 and easily flows from the first inlet 11 into the circulating path 10.

The wind A which taken into the circulating path 10 flows in the width direction (the −Y direction) of the housing 2 along the circulating path 10, thereby cooling the wall surface of the circulating path 10 and the light emitting unit 31D of the lighting unit 3D. Furthermore, since the wind A directly cools the heat radiating portion 32 of the lighting unit 3D disposed in the circulating path 10, it is possible to improve the heat exhaust effect (the cooling effect) of the light emitting unit 31D. After that, the wind A which has cooled the light emitting unit 31D is discharged from the outlet 12 to the outside of the housing 2.

### Effect of Heat-Exhausting Device

As described above, in the heat-exhausting device 1B according to the present embodiment, the first inlet 11 has the rib 27 extending toward the rear side in the travel direction of the vehicle V.

Thus, since the wind A generated when the vehicle V travels in the lane L is guided toward the first inlet 11 by the rib 27, the wind A is easily taken into the circulating path 10.

Also, the fee machine 101 according to the present embodiment includes the heat-exhausting device 1E and the lighting unit 3D (the processing unit 3).

Thus, the fee machine 101 can take the wind A generated when the vehicle V travels in the lane L into the housing 2 of the fee machine 101 and exhaust heat of or cool the light emitting unit 31D of the lighting unit 3D (the heat-generating portion of the processing unit 3).

The circulating path 10 of the heat-exhausting device 1E according to the present embodiment may be configured so that the cross-sectional area of the downstream side of the circulating path 10 is larger than that of the upstream side, in the same way as the second embodiment. Furthermore, the circulating path 10 of the heat-exhausting device 1E according to the present embodiment may further include the propeller 41, the sensor 42, and the battery 43, in the same way as the third embodiment.

### Modified Example of Fifth Embodiment

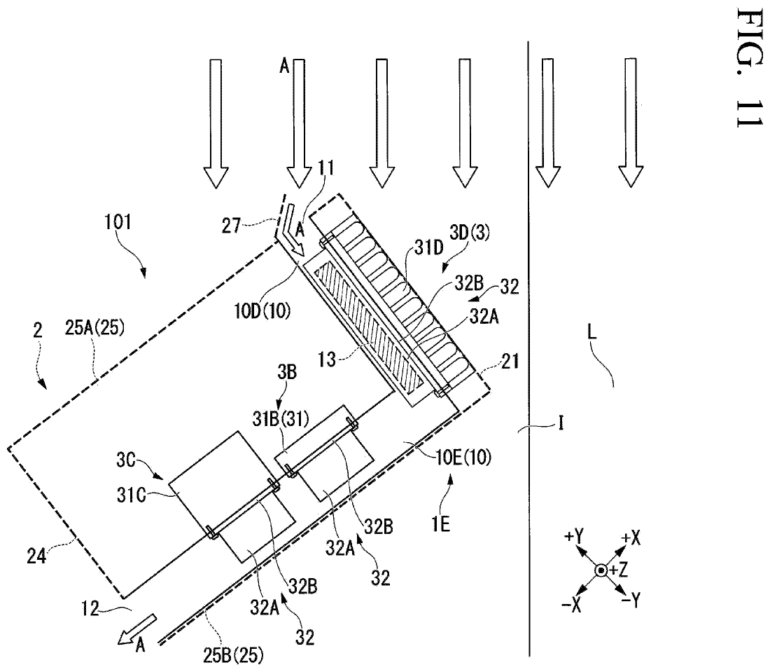

FIG. 11 is a cross-sectional view of a fee machine and a heat-exhausting device according to a modified example of the fifth embodiment of the present invention.

A heat-exhausting device 1F according to the modified example includes an L-shaped circulating path 10. For example, as shown in FIG. 11, the circulating path 10 has a structure including a first flow path 10D extending in the width direction (the ±Y direction) of a housing 2 from a first inlet 11 and a second flow path 10E extending to the rear side (the −X side) of the housing 2 along the side surface 25 of the housing 2.

Also, a fee machine 101 according to the modified example includes a plurality of processing units 3. For example, the fee machine 101 includes a substrate 3B and a power supply unit 3C as the processing units 3 in addition to a lighting unit 3D as in the fourth embodiment.

The heat-generating portions (the light emitting unit 31D, the CPU 31B, and the power supply portion 31C) of the lighting unit 3D, the substrate 3B, and the power supply unit 3C are disposed to be in contact with an outer wall surface of the circulating path 10. Furthermore, the heat radiating portions 32 of the substrate 3B and the power supply unit 3C are disposed inside the circulating path 10 as in each of the above embodiments. The disposition of the lighting unit 3D, the substrate 3B, and the power supply unit 3C shown in FIG. 11 is an example and can be arbitrarily changed in accordance with the structure of the fee machine 101.

As described above, the heat-exhausting device 1F in the modified example includes the circulating path 10 bending in an L shape and heat-generating portions of a plurality of processing units 3 are disposed in contact with the outer wall surface of the circulating path 10.

Thus, the heat-exhausting device 1E can simultaneously exhaust heat of or cool the heat-generating portions of the plurality of processing units 3 by one circulating path 10.

Although the embodiments of the present invention have been described in detail above, the present invention is not limited to these as long as the present invention does not deviate from the technical idea of the present invention and some design changes and the like are possible.

For example, although an example in which the vehicle V is a road maintenance work vehicle and the vehicle-mounted device 100 is a vehicle-mounted indicator has been described in the above embodiments, the present invention is not limited thereto.

In another embodiment, the vehicle V may be a construction truck or the like and the vehicle-mounted device 100 may be a lighting device mounted on the construction truck or the like. In this case, the vehicle-mounted device 100 includes a lighting unit as the processing unit 3.

Also, although an example in which the fee machine 101 is a license plate reading device has been described in the above embodiments, the present invention is not limited thereto. In another embodiment, the fee machine 101 may be a display board for displaying a usage fee or the like. In this case, the processing unit 3 of the fee machine 101 is a display unit.

In still another embodiment, the fee machine 101 may be a barrier gate which regulates a vehicle V from leaving a tollbooth before paying a usage fee. In this case, the processing unit 3 of the fee machine 101 is an actuator for opening and closing a bar of the barrier gate for restricting the exit of the vehicle V.

### INDUSTRIAL APPLICABILITY

According to the heat-exhausting device, the vehicle-mounted device, and the fee machine described above, it is possible to exhaust heat of the heat-generating portion of the process unit only with a compact and simple structure.

### REFERENCE SIGNS LIST

100 Vehicle-mounted device
101 Fee machine
1A to 1F Heat-exhausting device
10 Circulating path
11 First inlet
12 Outlet
13 Second inlet
2 Housing
27 Rib
3 Processing unit
3A Display unit (processing unit)
31A Display portion (heat-generating portion)
3B Substrate (processing unit)
31B CPU (heat-generating portion)
3C Power supply unit (processing unit)
31C Power supply portion (heat-generating portion)
3D Lighting unit (processing unit)
31D Light emitting unit (heat-generating portion)
32 Heat radiating portion
32A Fin
32B Base portion
41 Propeller
42 Sensor
43 Battery

1. A heat-exhausting device, comprising:
a first inlet through configured to take wind generated by traveling of a vehicle into a housing; and
a circulating path through which the wind taken from the first inlet is allowed to flow in the housing,
wherein a heat-generating portion of a processing unit configured to perform a predetermined process when the processing unit is energized is disposed in contact with an outer wall surface of the circulating path.

2. The heat-exhausting device according to claim 1, wherein a heat radiating portion attached to the heat-generating portion of the processing unit is disposed inside the circulating path.

3. The heat-exhausting device according to claim 1, wherein a second inlet is configured to take the wind into the housing is provided in the circulating path on a downstream side compared with the first inlet.

4. The heat-exhausting device according to claim 3, wherein the second inlet is open in an upper surface of the housing.

5. The heat-exhausting device according to claim 3, wherein a cross-sectional area of the circulating path on the downstream side is larger than a cross-sectional area of the circulating path on an upstream side.

6. The heat-exhausting device according to claim 1, further comprising:
a propeller provided in the circulating path; and
a battery configured to be charged with electricity by a rotation of the propeller caused by the wind.

7. The heat-exhausting device according to claim 6, wherein the battery is configured to supply electric power to the propeller when the rotation of the propeller stops.

8. A vehicle-mounted device, comprising:
the heat-exhausting device according to claim 1; and
the processing unit.

9. A fee machine provided on a roadside of a lane, comprising:
the heat-exhausting device according to claim 1; and
the processing unit.
